(19) United States
(12) Patent Application Publication
(10) Pub. No.: US 2008/0061832 A1
(43) Pub. Date: Mar. 13, 2008

(54) Protection circuits and methods of protecting circuits

(76) Inventors: Fang-Ling Hu, Yilan County (TW); Ming-Dou Ker, Hsinchu City (TW)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(21) Appl. No.: 11/649,551

(22) Filed: Jan. 3, 2007

Related U.S. Application Data
(60) Provisional application No. 60/823,453, filed on Aug. 24, 2006.

(51) Int. Cl. H03K 19/094

(52) U.S. Cl. 326/83

(57) ABSTRACT

A circuit configured for providing hot-carrier effect protection, the circuit comprising a first transistor including a first terminal and a second terminal, the first terminal being coupled to a conductive pad, a switch device including a terminal coupled to the conductive pad, and a control circuit configured for keeping the switch at an off state during a receiving mode at which a signal of a first voltage level or a reference level is received at the conductive pad, keeping the switch at the off state during a transmitting mode from which a signal of a second voltage level or the reference level is transmitted at the conductive pad, and keeping the switch at an on state during a transition from the receiving mode when receiving a signal of the first voltage level to the transmitting mode when transmitting a signal having the reference voltage level, wherein during the transition a voltage across the first terminal and the second terminal of the first transistor is maintained at a level below approximately the first voltage level minus the second voltage level.

### CROSS-REFERENCE TO RELATED APPLICATIONS

This application claims the benefit of U.S. Provisional Application No. 60/823,453, filed Oct. 6, 2006.

### BACKGROUND OF THE INVENTION

The present invention relates generally to circuits and methods for protecting a circuit or buffer, and more particularly, to a circuit configured for preventing the hot-carrier effect in a mixed-voltage input/output (I/O) buffers.

With the progress in complementary metal-oxide-semiconductor (CMOS) manufacturing technologies, the dimensions of transistors have been scaled down to reduce the silicon cost as well as to meet the increasing demands for more reliable circuit performance and faster operating speed. The thinner gate oxide of a CMOS transistor helps reduce the core power supply voltage (VDD) and therefore achieves lower power consumption. However, the maximum tolerable voltage across the transistor terminals (drain, source, gate and bulk) should be decreased accordingly to ensure the lifetime of the CMOS transistor.

As an illustrative example, with back compatibility to earlier defined standards or interface protocols of CMOS integrated circuits (ICs) in a microelectronics system, the chips fabricated in advanced CMOS processes operating in the VDD domain may receive input signals with voltage levels (VDDH) higher than VDD. For example, the VDDH and VDD voltage levels are approximately 3.3 volts (V) and 1.5V, respectively, in the Peripheral Component Internet Extended (PCI-X) 2.0 applications. Such mixed-voltage input/output (I/O) interfaces must be designed to overcome several problems, such as gate-oxide reliability, hot-carrier degradation and undesired circuit leakage paths between chips. The hot-carrier induced degradation, among others, has become one of the reliability concerns in metal-oxide-semiconductor field effect transistor (MOSFET) devices fabricated in deep sub-micron technologies, which feature short channel length and high electric field. The hot-carrier effect refers to a phenomenon that carriers are accelerated by channel electric fields and become trapped in a gate oxide. The hot-carrier effect may incur deviation of threshold voltage (Vₜₕ), undesirable transconductance (gₘ), and linear (I_{DLIN}) and saturation (I_{DSAT}) drain currents, resulting in degradation or even failure of a transistor.

FIG. 1 is an exemplary simplified circuit diagram of a buffer 10 in a mixed-voltage interface. Referring to FIG. 1 as an example, the buffer 10 includes a pre-driver 11, a post-driver or output circuit 12, an input circuit 13 and an I/O pad 14. The pre-driver 11 and the input circuit 13 are simplified into function blocks for convenience. The pre-driver 11 generates control signals PU and PD in response to an output enable (OE) signal and a data output (Dout) signal from an internal circuit (not shown), respectively. The post-driver 12 further includes a pull-up network 121 and a pair of stacked transistors MN0 and MN1, which are thin-oxide devices tolerant of the VDDH level. The pull-up network 121, which is simplified into a function block, includes a terminal for receiving the control signal PU. The gates of the transistors MN0 and MN1 are respectively connected to the VDD line and the pre-driver 11 to receive the control signal PD. The buffer 10 receives input signals of the VDDH level through the I/O pad 14 to the input circuit 13, and transmits output signals of the VDD level from an input terminal Dₒᵤₜ to the I/O pad 14. During the transition from the receiving operation to the transmitting operation, the transistor MN0 may be susceptible to the hot-carrier effect, which will be discussed in detail.

FIG. 2 is a schematic cross-sectional view of an n-type metal-oxide-semiconductor (NMOS) transistor 20. Referring to FIG. 2, the NMOS transistor 20 includes a heavily doped n-type source 20-S and a heavily doped n-type drain 20-D formed in a p-type substrate, a thin layer of silicon dioxide 20-O grown over the substrate, and a conductive gate material 20-G formed over the dioxide 20-O between the source 20-S and the drain 20-D. The source 20-S is connected to ground. In operation, the gate-to-source voltage may modify the conductance of a region under the gate 20-G, allowing a gate voltage to control a current following between the source 20-S and the drain 20-D. When positive voltages, V_{G} and V_{D}, are applied to the gate 20-G and the drain 20-D, respectively, an inversion layer is produced as the V_{G} is equal to or larger than the threshold voltage (Vₜₕ) of the NMOS transistor 20. When the value of V_{D} is increased, the induced conducting channel narrows at the drain end. The induced electron charge at the drain end approaches zero as V_{D} approaches (V_{G}−Vₜₕ). That is, the channel is no longer connected to the drain 20-D when V_{D} is greater than (V_{G}−Vₜₕ), which is known as pinch-off. At this time, the electric field may start to rise dramatically at the pinch-off point of the NMOS transistor 20. In the high electric field, carriers are accelerated to high velocities, reaching a maximum kinetic energy (hot) near the drain 20-D. If the carrier energy is high enough, impact ionization can occur, creating electron-hole pair 21. The generated electrons in the electron-hole pair 21 called secondary electrons tend to be swept to the drain 20-D. Furthermore, the generated holes in the electron-hole pair 21 called secondary holes may be swept into the substrate in the NMOS transistor 20.

Some of the electrons generated in the space charge region are attracted to the oxide 20-O due to the electric field induced by the positive gate voltage, V_{G}. These generated electrons have energies far greater than the thermal-equilibrium value and are called hot electrons (or hot carriers) 22. If the hot electrons 22 have energies on the order of 1.5 electron volt (eV), they may be able to tunnel into the oxide 20-O. In some cases the generated holes and electrons can attain enough energy to surmount the Si—SiO₂ barrier and become trapped in the gate oxide 20-O. The charge trapping in interface states may disadvantageously cause a shift in the threshold voltage, additional surface scattering, and reduced mobility. The hot electron charging effects are continuous processes, so the NMOS transistor 20 degrades over a period of time.

Referring again to FIG. 1, the hot-carrier induced degradation or gate-oxide reliability in the VDDH-tolerant I/O buffer 10 may exist in the following two states: (1) the state of receiving VDDH input signals, and (2) the state of a transition from receiving VDDH input signals to transmitting 0-V output signals. When the VDDH-tolerant I/O buffer 10 receives VDDH input signals, the PU and PD signals are kept at VDD and 0 V, respectively, to disable the output circuit 12. Since the transistor MN1 is turned off, the transistor MN0 is weakly turned “on”, which results in a voltage of about VDD at the source of the transistor MN0. In each of the stacked transistors MN0 and MN1, the voltages drop across the gate-oxide and the drain-source are both lower than or equal to the supply voltage (VDD). Therefore, there is neither hot-carrier degradation nor gate-oxide overstress issue in the mixed-voltage I/O buffer 10 when receiving VDDH input signals.

During a transition from receiving VDDH input signals to transmitting 0-V output signals, the I/O pad 14 originally has a voltage of VDDH before being pulled down. At this transition moment, the transistor MN1 is turned on by the PD signal from the pre-driver 11, and the transistor MN0 is subsequently switched on when its source is pulled down by the transistor MN1. The voltage at the drain of the transistor MN1 may be approximated as the saturation drain voltage (V_{DSAT}). For example, the voltage at the source of the transistor MN0 is approximately 0.5V in a 0.18-μm CMOS process. Since the original VDDH voltage at the I/O pad 14 is not pulled down immediately, the drain-to-source voltage of the transistor MN0 is greater than the normal supply voltage (VDD) during this transition, which results in the significant hot-carrier degradation in the transistor MN0.

It may therefore be desirable to have a circuit that may protect a circuit, such as an I/O buffer, from the hot-carrier effect. It may also be desirable to have a buffer circuit that may be immune from the hot-carrier effect.

### BRIEF SUMMARY OF THE INVENTION

Examples of the present invention may provide a circuit configured for providing hot-carrier effect protection, the circuit comprising a first transistor including a first terminal and a second terminal, the first terminal being coupled to a conductive pad, a switch device including a terminal coupled to the conductive pad, and a control circuit configured for keeping the switch at an off state during a receiving mode at which a signal of a first voltage level or a reference level is received at the conductive pad, keeping the switch at the off state during a transmitting mode from which a signal of a second voltage level or the reference level is transmitted at the conductive pad, and keeping the switch at an on state during a transition from the receiving mode when receiving a signal of the first voltage level to the transmitting mode when transmitting a signal having the reference voltage level, wherein during the transition a voltage across the first terminal and the second terminal of the first transistor is maintained at a level below approximately the first voltage level minus the second voltage level.

Some examples of the present invention may also provide a circuit configured for providing hot-carrier effect protection, the circuit comprising a conductive pad at which a signal of a first voltage level or a reference level is received during a receiving mode and from which a signal of a second voltage level or the reference voltage level is transmitted, a first transistor including a first terminal and a second terminal, the first terminal being coupled to the conductive pad, and a control circuit configured for maintaining a voltage across the first terminal and the second terminal of the first transistor at a level below approximately the first voltage level minus the second voltage level during a transition from the receiving mode when receiving a signal of the first voltage level to the transmitting mode when transmitting a signal of the reference level.

Examples of the present invention may further provide a circuit configured for providing hot-carrier effect protection, the circuit comprising a conductive pad at which a signal of a first voltage level or a reference level is received during a receiving mode and from which a signal of a second voltage level or the reference voltage level is transmitted, a first transistor including a first terminal and a second terminal, a second transistor including a third terminal coupled to the first terminal and a fourth terminal coupled to the conductive pad, and a first control circuit configured for maintaining a voltage across the first terminal and the second terminal of the first transistor at a level below approximately the first voltage level minus the second voltage level during a first transition from the receiving mode when receiving a signal of the first voltage level to the transmitting mode when transmitting a signal of the second voltage level.

Examples of the present invention may also provide a method of protecting a circuit from hot-carrier effect protection, the method comprising providing a first transistor including a first terminal and a second terminal, coupling the first terminal of the first transistor to a conductive pad, providing a switch device including a terminal, coupling the terminal of the switch device to the conductive pad, keeping the switch at an off state during a receiving mode at which a signal of a first voltage level or a reference level is received at the conductive pad, keeping the switch at the off state during a transmitting mode from which a signal of a second voltage level or the reference level is transmitted at the conductive pad, keeping the switch at an on state during a transition from the receiving mode when receiving a signal of the first voltage level to the transmitting mode when transmitting a signal having the reference voltage level, and maintaining a voltage across the first terminal and the second terminal of the first transistor at a level below approximately the first voltage level minus the second voltage level during the transition.

Additional features and advantages of the present invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings examples which are presently preferred. It should be understood, however, that the invention is not limited to the precise arrangements and instrumentalities shown.

In the drawings:

FIG. 1 is a simplified circuit diagram of a buffer in a mixed-voltage interface;

FIG. 2 is a schematic cross-sectional view of an n-type metal-oxide-semiconductor (NMOS) transistor;

FIG. 3A is a schematic block diagram of a buffer circuit in a mixed-voltage interface consistent with an example of the present invention;

FIG. 3B is an exemplary circuit diagram of the buffer circuit illustrated in FIG. 3A;

FIG. 4 is a schematic circuit diagram of a buffer circuit consistent with an example of the present invention; and

FIGS. 5A to 5C are plots illustrating simulation results of the buffer circuit illustrated in FIG. 4.

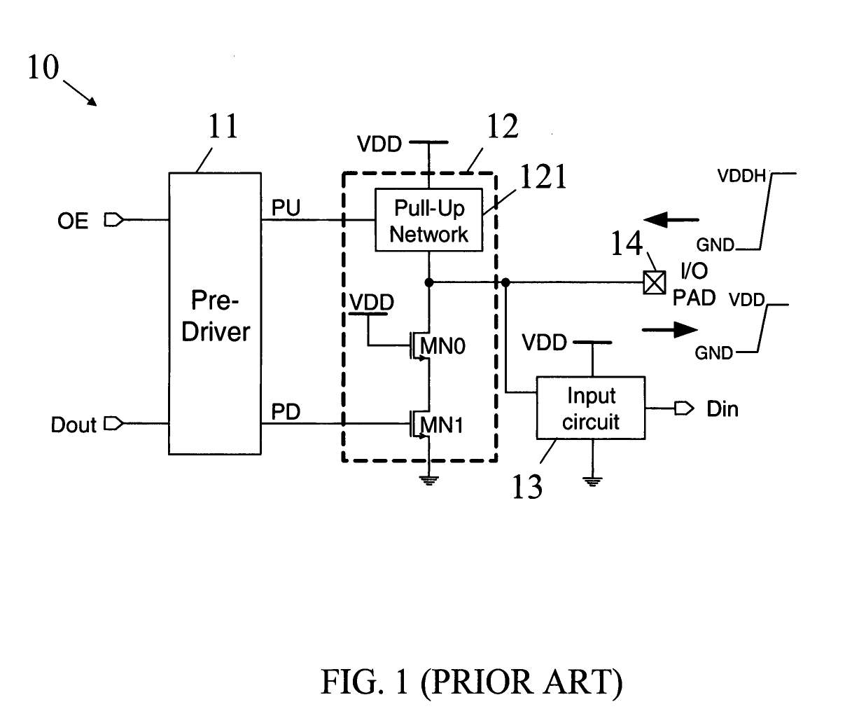

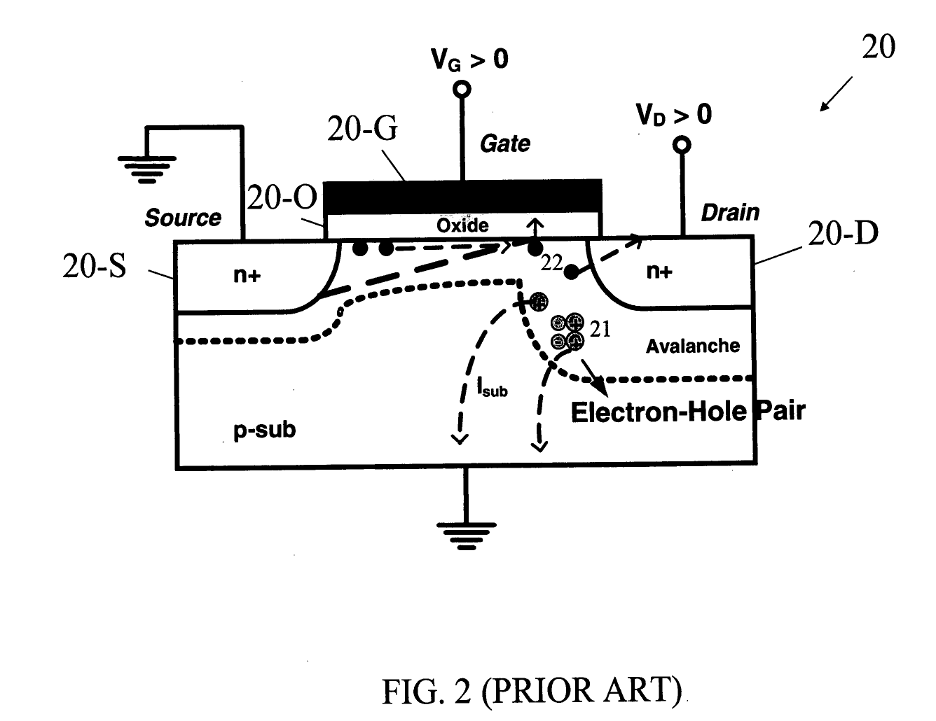

### DETAILED DESCRIPTION OF THE INVENTION

Reference will now be made in detail to the present examples of the invention, examples of which are illustrated in the accompanying drawings. Wherever possible, the same reference numbers will be used throughout the drawings to refer to the same or like parts.

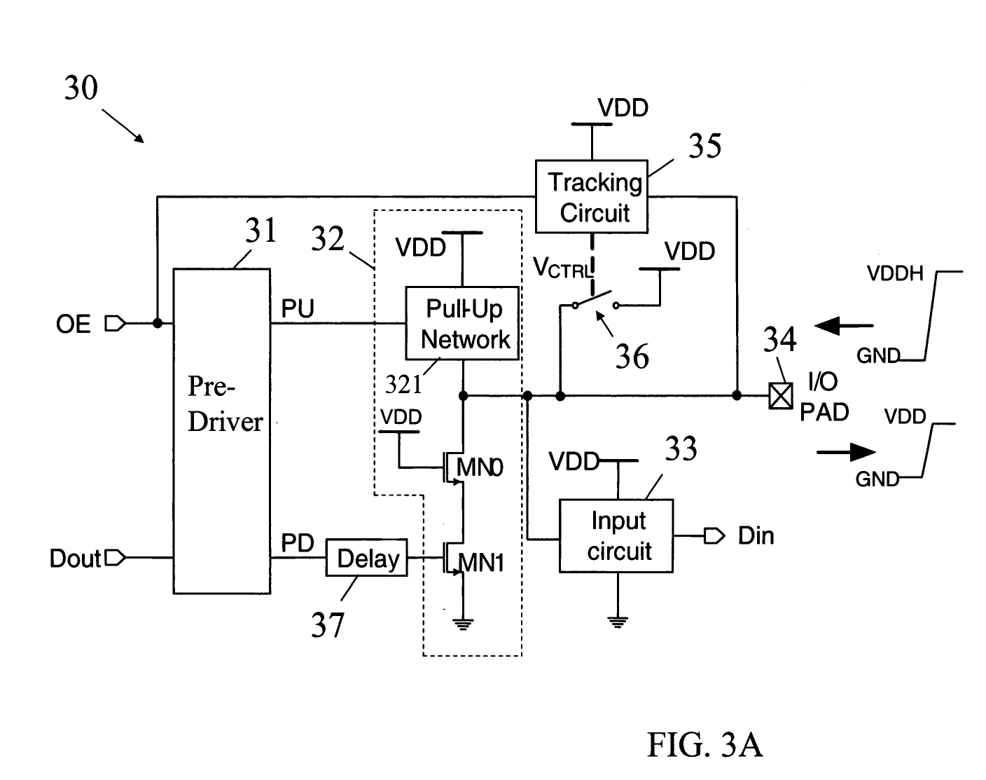

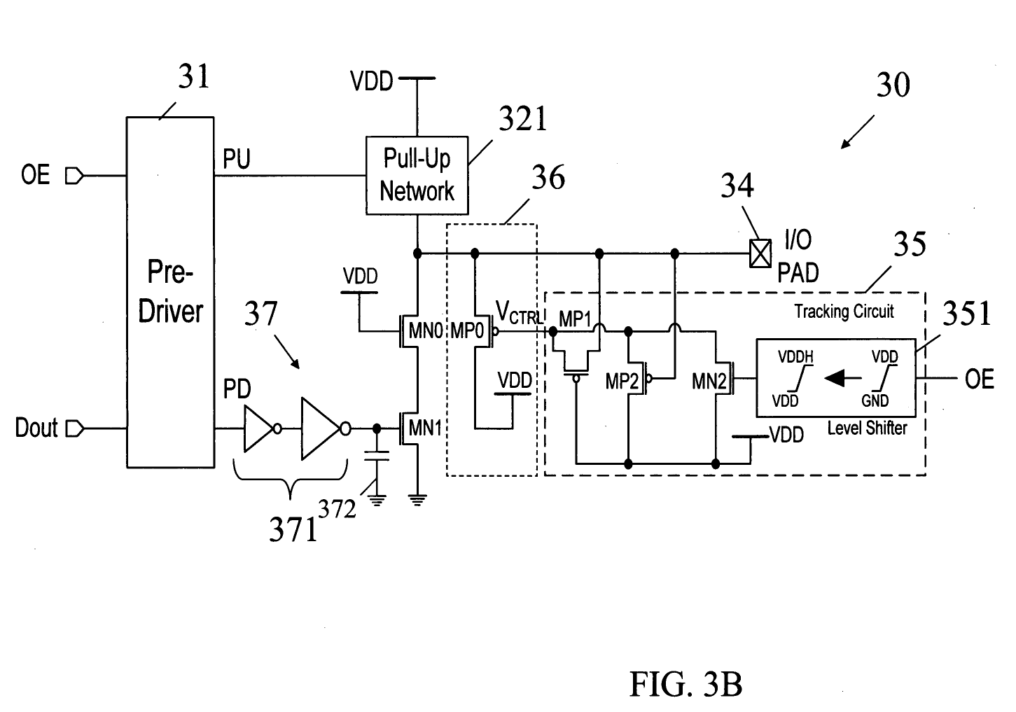

FIG. 3A is a schematic block diagram of a buffer circuit 30 in a mixed-voltage interface consistent with an example of the present invention. Referring to FIG. 3A, the buffer circuit 30 may include a pre-driver 31, a post-driver or output circuit 32, an input circuit 33, an input/output (I/O) pad 34, a tracking circuit 35 and a switch device 36. The post-driver 32 may further include a pull-up network 321 and stacked NMOS transistors MN0 and MN1. The pre-driver 31, the pull-up network 321 and the input circuit 33 are simplified into function blocks for convenience. The pre-driver 31 generates control signals PU and PD in response to an output enable (OE) signal and a data output (Dout) signal from an internal circuit (not shown), respectively. The stacked transistors MN0 and MN1 are, for example, thin-oxide devices tolerant of a VDDH level. The pull-up network 321 includes a terminal (not numbered) for receiving the control signal PU. The transistor MN0 includes a gate (not numbered) connected to a VDD line, and the transistor MN1 includes a gate (not numbered) connected to the pre-driver 31 to receive the control signal PD through a delay cell 37. The buffer circuit 30 may operate in a receiving mode to receive input signals of the VDDH level to the input circuit 33 through the I/O pad 34, and may operate in a transmitting mode to transmit output signals of the VDD level through the post-driver 32 to the I/O pad 34. The VDDH voltage level is greater than the VDD level. In one example, the VDDH and VDD voltage levels are approximately 3.3V and 1.5V, respectively.

The tracking circuit 35 includes a first terminal (not numbered) coupled to the OE signal, a second terminal (not numbered) connected to the I/O pad 34, and a third terminal (not numbered) connected to the switch device 36. The tracking circuit 35 is configured for generating a control signal V_{CTRL} in response to the OE signal to control the state of the switch device 36. During a transition from receiving VDDH input signals to transmitting 0-V output signals, the switch device 36 is turned on by the control signal V_{CTRL} to pull down the voltage level at the I/O pad 34 to VDD. The delay cell 37 provides a delay long enough to have the I/O pad 34 pulled down to VDD before the transistor MN1 is turned on by the control signal PD. Thus, the drain-to-source voltage of the transistor MN0 during the transition may not exceed its maximum normal operation voltage range (VDD), which prevents the transistor MN0 from the hot-carrier degradation. The switch device 36 is kept off in the receiving and transmitting modes and thus does not interfere with the normal operation of the buffer circuit 30 in both the receiving and transmitting modes. The switch device 36 is not switched on until there is a transition from receiving an input VDDH signal to transmitting an output 0-V signal.

FIG. 3B is a circuit diagram of the buffer circuit 30 illustrated in FIG. 3A. For the purpose of convenience, the input circuit 33 illustrated in FIG. 3A is omitted. Referring to FIG. 3B, the tracking circuit 35 may include a level shifter 351, an NMOS transistor MN2 and PMOS transistors MP1 and MP2. The level shifter 351 is configured for shifting a ground voltage level to the VDD level in response to the OE signal in the receiving mode, and shifting the VDD level to the VDDH level in response to the OE signal in the transmitting mode. The transistor MN2 includes a gate connected to the level shifter 351, a drain connected to VDD, and a source connected to a gate of the transistor MP0. Skilled persons in the art will understand that the source and drain of a MOS transistor are exchangeable, depending on the voltage levels applied thereto. The transistor MP2 includes a gate connected to the I/O pad 34, a source connected to VDD, and a drain connected to the gate of the transistor MP0. The transistor MP1 includes a gate connected to the VDD, a source connected to the I/O pad 34, and a drain connected to the gate of the transistor MP0.

The switch device 36 may include a PMOS transistor MP0 further including a gate connected to the source of the transistor MN2, a source connected to the VDD, and a drain connected to the I/O pad 34.

The delay cell 37 may include an inverter chain 371. In one example according to the present invention, the delay cell 37 further includes a capacitor 372 between the output of the inverter chain 371 and the gate of the transistor MN1 to provide a desirable delay time. The desirable delay time Δt may be estimated in an equation below.

ΔQ=C_{L}ΔV=I₃₆Δt

wherein C_{L} is an output loading, ΔV is the difference between VDDH and VDD, i.e., VDDH-VDD, and 136 is a driving current of the switch device 36.

When the buffer circuit 30 operates in the receiving mode, the output enable signal OE is set to 0V, and the control signals PU and PD are VDD and 0V, respectively. The level shifter 351 sets the gate of the transistor MN2 to VDD. When receiving input signals of the VDDH level, the transistor MP1 is switched on, which sets V_{CTRL} to the VDDH level so that a leakage path to the VDD line through the transistor MP0 during the receiving mode may be prevented. When receiving input signals of the 0V level, due to a significant gate-to-source voltage, the transistor MP2 is switched on, which sets V_{CTRL} to the VDD level during the receiving mode. During the receiving mode, either receiving input signals of the VDDH level or the 0V level, the transistor MP0 is maintained at an off state.

When the buffer circuit 30 operates in the transmitting mode, the OE signal is set to VDD. Both of the control signals PU and PD are set to VDD when transmitting output signals of the 0V level and set to 0V when transmitting output signals of the VDD level. The gate voltage of the transistor MN2 is pulled up to the VDDH level by the level shifter 351. The transistor MN2 is switched on, which sets V_{CTRL} to the VDD level. The transistor MP0 is maintained at the off state by the V_{CTRL} of the VDD level during the transmitting mode. As a result, the transistor MP0 is turned off in both of the steady-states, i.e., the receiving mode and transmitting mode, and does not adversely affect the correct operations. In the steady states, the gate-oxide degradation and hot-carrier degradation are prevented in the buffer circuit 30.

During a transition from the state of receiving VDDH input signals to the state of transmitting 0-V output signals, the gate terminal of the transistor MN1 is maintained at 0V while the PD signal is changing from 0V to VDD by the pre-driver 31. In the meanwhile, the V_{CTRL} is set to the VDD level as the transistor MN2 is switched on in response to the OE signal. Subsequently, the transistor MP0 is turned on due to a significant gate-to-source voltage, and discharges the initial voltage of VDDH at the I/O pad 34. After hundreds of picoseconds, for example, the voltage at I/O pad 34 is pulled down to approximately the VDD level, and the gate voltage of the transistor MN1 increases to the VDD level after a delay induced by the inverter chain 371. Therefore, the drain-to-source voltage of the transistor MN0 is kept within the maximum normal operating voltage (V_{dd,nom}) range during the transition, resulting in no hot-carrier degradation. The V_{dd,nom} equals to approximately VDDH minus VDD. In the present example, the V_{dd,nom} is approximately 1.8V, given the VDD and VDDH being 1.5V and 3.3V, respectively.

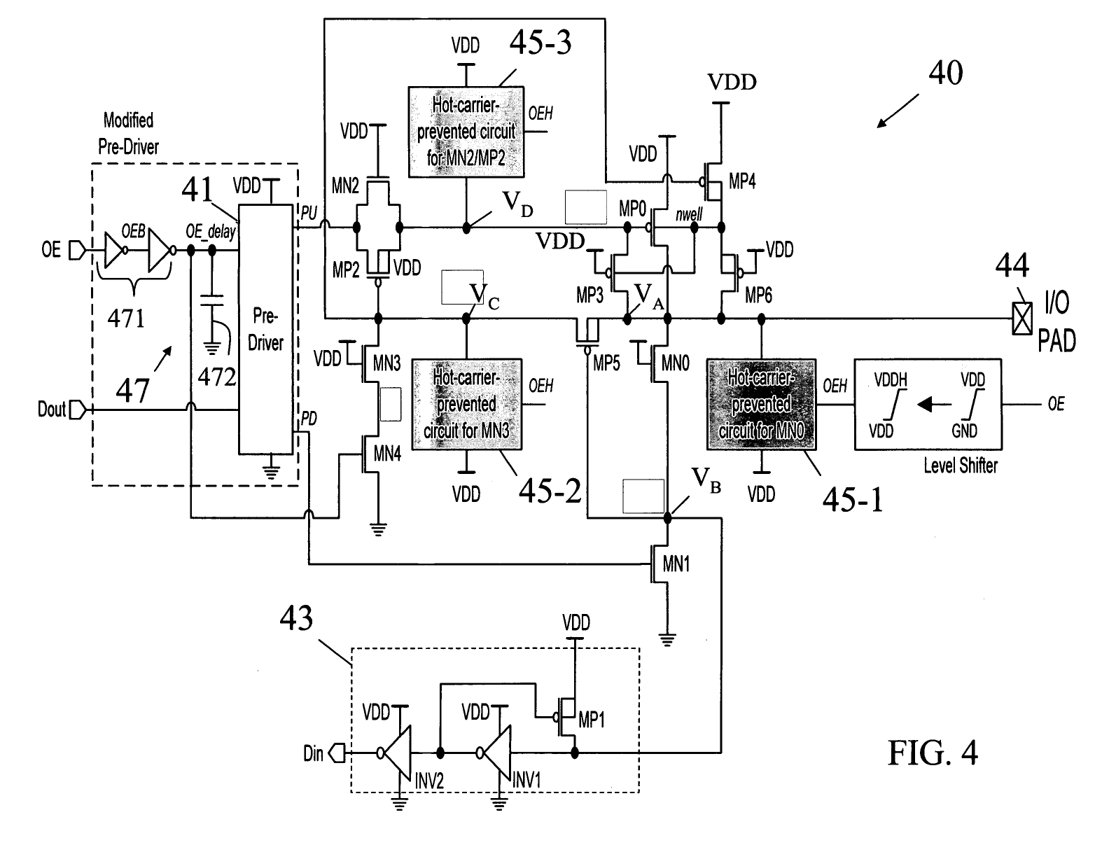

FIG. 4 is a schematic circuit diagram of a buffer circuit 40 consistent with an example of the present invention. Referring to FIG. 4, the buffer circuit 40 includes a pre-driver 41, an input circuit 43, an I/O pad 44, a first hot-carrier-prevented (HCP) circuit 45-1, a second HCP circuit 45-2 and a third HCP circuit 45-3. Each of the HCP circuits 45-1, 45-2 and 45-3 includes a tracking circuit and a transistor controlled by the tracking circuit, which are similar in function to the tracking circuit 45 and the PMOS transistor MP0 illustrated in FIG. 3B. In one example according to the present invention, the buffer circuit 40 further includes a delay cell 47, which includes an inverter chain 471 connected between the output enable signal OE and the pre-driver 41. An output of the inverter chain 471 is connected to the gate of a transistor MN4. The delay cell 47 may further include a capacitor 472 connected between the output of the inverter chain 471 and the pre-driver 41 to provide a desirable delay time.

During a transition from receiving VDDH input signals to transmitting 0-V output signals, the transistor MN0 may risk the hot-carrier degradation due to a voltage V_{A} (which equals VDDH at the beginning of the transition) at the drain of the transistor MN0. With the first HCP circuit 45-1, the voltage V_{A} is pulled down to the VDD level so that the transistor MN0 is protected from the hot-carrier degradation.

Meanwhile, at the beginning of the transition, the transistor MN0 is weakly turned on so that V_{B} is approximately VDD. The transistor MP5 is turned on because its gate and source are biased at V_{B} (VDD) and V_{A} (VDDH), respectively, which pulls V_{C} to V_{A} (VDDH). Similarly, during the transition from receiving VDDH input signals to transmitting 0-V output signals, the transistor MN3 may risk the hot-carrier degradation due to the voltage V_{C} (VDDH) at the drain of the transistor MN3. With the second HCP circuit 45-2, the voltage V_{C} is pulled down to VDD so that the transistor MN3 is protected from the hot-carrier degradation.

Furthermore, at the beginning of the transition, the transistor MP3 is turned on because its gate and source are biased at VDD and V_{A} (VDDH), respectively, which pulls V_{D} to V_{A} (VDDH). During a transition from receiving VDDH input signals to transmitting VDD output signals, the control signal PU is set to 0V such that the transistors MN2 and MP2 may risk the hot-carrier degradation. With the third HCP circuit 45-3, the voltage V_{D} is pulled down to VDD so that the transistors MN2 and MP2 are protected from the hot-carrier degradation.

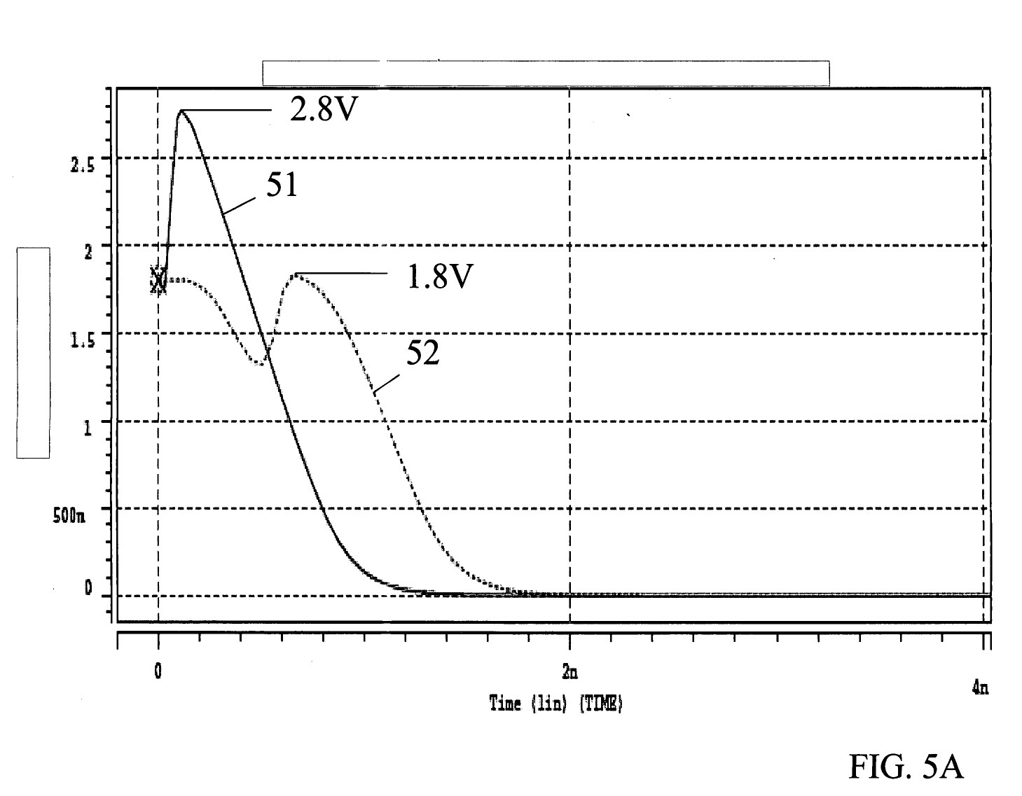

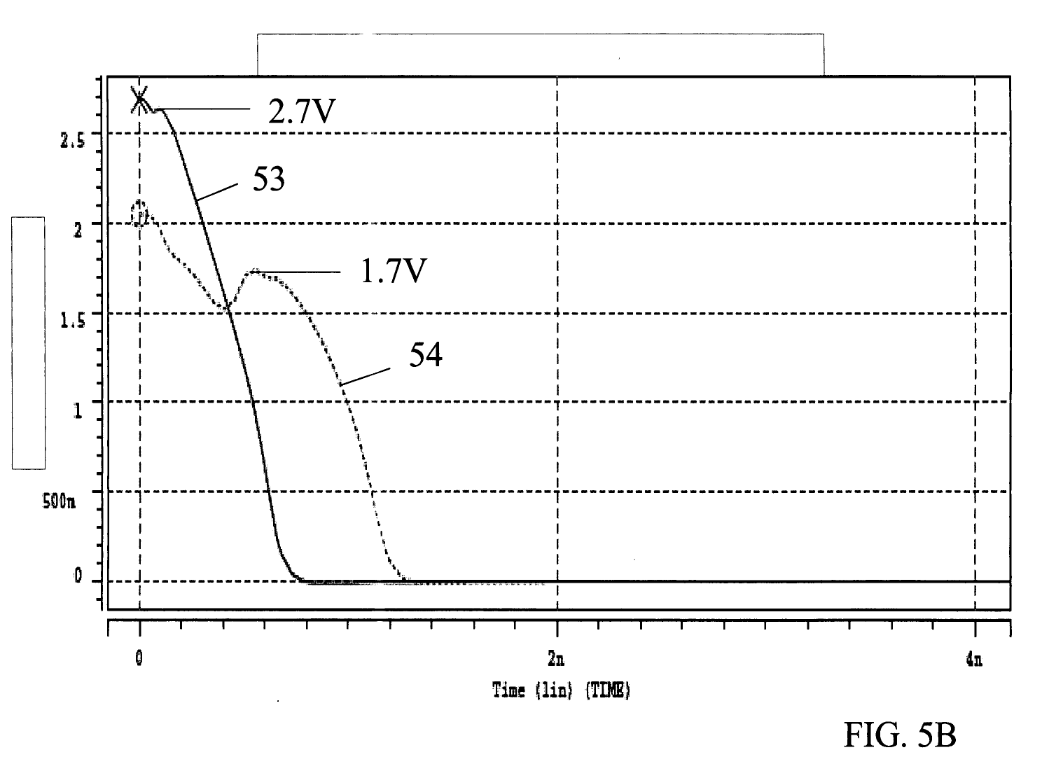

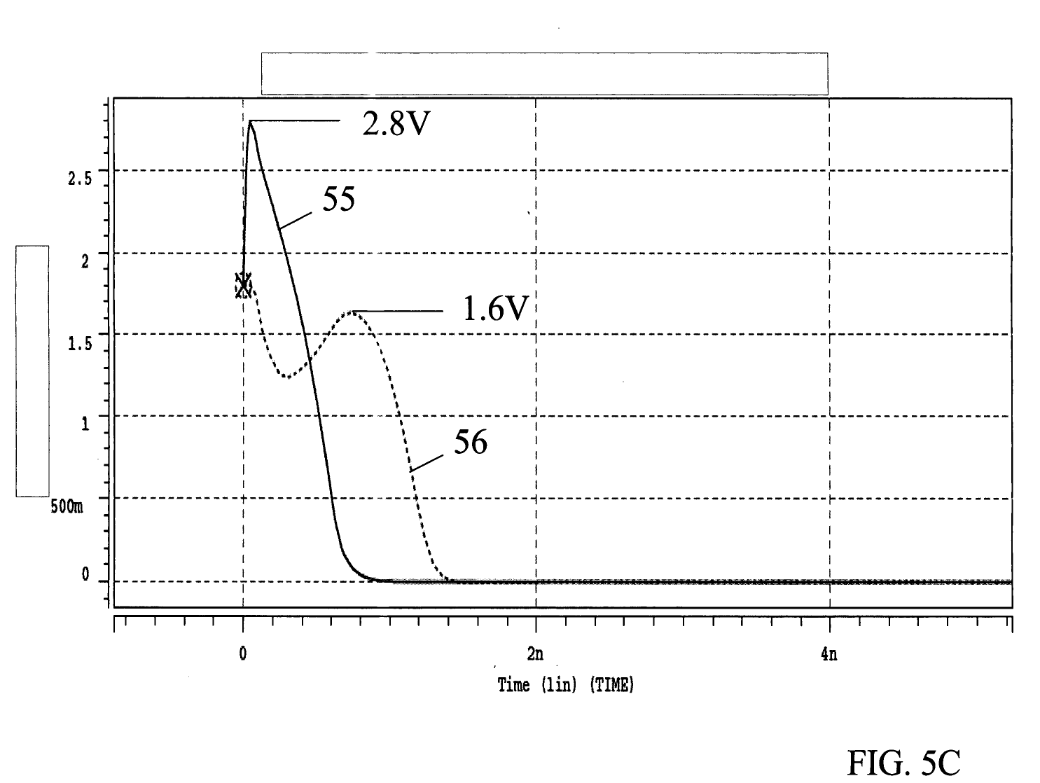

FIGS. 5A to 5C are plots illustrating simulation results of the buffer circuit 40 illustrated in FIG. 4. The buffer circuit 40 meets the PCI-X 2.0 applications in a given 0.18-μm CMOS process, and transmits 0V-to-1.5V output signals and receives 0V-to-3.3V input signals. Furthermore, the buffer circuit 40 has an operating speed up to 266 mega Hertz (MHz). The hot-carrier effect is verified by Simulated Program with Integrated Circuits Emphasis (SPICE) simulation in a 0.18-μm CMOS process.

Referring to FIG. 5A, the drain-to-source voltage of the transistor MN0 during the transition from receiving 3.3-V input signals to transmitting 0-V output signals is represented by a curve 52 illustrated in dotted lines. The peak of drain-to-source voltage of the transistor MN0 is only approximately 1.8V, which is remarkably lower than that (2.8V) of a conventional buffer circuit represented by a curve 51. Furthermore, the curve 52 is shifted relative to the curve 51 in the time axis due to a function of the delay cell 47.

Referring to FIG. 5B, the drain-to-source voltage of the transistor MN3 during the transition from receiving 3.3-V input signals to transmitting 0-V output signals is represented by a curve 54 illustrated in dotted lines. The peak of drain-to-source voltage of the transistor MN3 is only approximately 1.7V, which is remarkably lower than that (2.7V) of a conventional buffer circuit represented by a curve 53.

Referring to FIG. 5C, the drain-to-source voltage of the transistor MN2 (or MP2) during the transient from receiving 3.3-V input signal to transmitting 1.5-V output signal is represented by a curve 56 illustrated in dotted lines. The peak of drain-to-source voltage of the transistor MN2 is only approximately 1.6V, which is remarkably lower than that (2.8V) of a conventional buffer circuit represented by a curve 55. Therefore, in view of the simulation results illustrated in FIGS. 5A to 5C, the potential hot-carrier effect on the transistors MN0, MN3, MN2 and MP2 has been suppressed by the HPC circuits 45-1, 45-2 and 45-3.

It will be appreciated by those skilled in the art that changes could be made to the examples described above without departing from the broad inventive concept thereof It is understood, therefore, that this invention is not limited to the particular examples disclosed, but it is intended to cover modifications within the spirit and scope of the present invention as defined by the appended claims.

Further, in describing representative examples of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

I claim:

1. A circuit configured for providing hot-carrier effect protection, the circuit comprising:
a first transistor including a first terminal and a second terminal, the first terminal being coupled to a conductive pad;
a switch device including a terminal coupled to the conductive pad; and
a control circuit configured for keeping the switch at an off state during a receiving mode at which a signal of a first voltage level or a reference level is received at the conductive pad, keeping the switch at the off state during a transmitting mode from which a signal of a second voltage level or the reference level is transmitted at the conductive pad, and keeping the switch at an on state during a transition from the receiving mode when receiving a signal of the first voltage level to the transmitting mode when transmitting a signal having the reference voltage level,
wherein during the transition a voltage across the first terminal and the second terminal of the first transistor is maintained at a level below approximately the first voltage level minus the second voltage level.

2. The circuit of claim 1, wherein the switch device includes a second transistor, the second transistor including a gate coupled to the control circuit.

3. The circuit of claim 2, wherein the control circuit includes a level shifter configured for providing the first voltage level during the transmitting mode, and providing the second voltage level during the receiving mode.

4. The circuit of claim 3, wherein the control circuit includes a third transistor further including a gate coupled to an output of the level shifter and a terminal coupled to the gate of the second transistor.

5. The circuit of claim 3, wherein the control circuit includes a fourth transistor further including a gate coupled to the conductive pad and a terminal coupled to the gate of the second transistor.

6. The circuit of claim 3, wherein the control circuit includes a fifth transistor further including a first terminal coupled to the conductive pad and a second terminal coupled to the gate of the second transistor.

7. The circuit of claim 1 further comprising a sixth transistor, wherein the sixth transistor includes a first terminal coupled to the second terminal of the first transistor.

8. The circuit of claim 7 further comprising a delay cell coupled to a gate of the sixth transistor.

9. The circuit of claim 8, wherein the delay cell includes an inverter string.

10. The circuit of claim 8, wherein the delay cell includes an inverter string and a capacitor coupled in parallel with the inverter string.

11. A circuit configured for providing hot-carrier effect protection, the circuit comprising:
a conductive pad at which a signal of a first voltage level or a reference level is received during a receiving mode and from which a signal of a second voltage level or the reference voltage level is transmitted;
a first transistor including a first terminal and a second terminal, the first terminal being coupled to the conductive pad; and
a control circuit configured for maintaining a voltage across the first terminal and the second terminal of the first transistor at a level below approximately the first voltage level minus the second voltage level during a transition from the receiving mode when receiving a signal of the first voltage level to the transmitting mode when transmitting a signal of the reference level.

12. The circuit of claim 11 further comprising a second transistor, wherein the control circuit is configured for turning off the second transistor during one of the receiving mode and the transmitting mode.

13. The circuit of claim 11 further comprising a second transistor, wherein the control circuit is configured for turning on the second transistor during the transition.

14. The circuit of claim 13, wherein the control circuit includes a level shifter configured for providing the first voltage level during the transmitting mode, and providing the second voltage level during the receiving mode.

15. The circuit of claim 14, wherein the control circuit includes a third transistor further including a gate coupled to an output of the level shifter and a terminal coupled to a gate of the second transistor.

16. The circuit of claim 14, wherein the control circuit includes a fourth transistor further including a gate coupled to the conductive pad and a terminal coupled to a gate of the second transistor.

17. The circuit of claim 14, wherein the control circuit includes a fifth transistor further including a first terminal coupled to the conductive pad and a second terminal coupled to a gate of the second transistor.

18. The circuit of claim 11 further comprising a sixth transistor, wherein the sixth transistor includes a first terminal coupled to the second terminal of the first transistor.

19. The circuit of claim 18 further comprising a delay cell coupled to a gate of the sixth transistor.

20. The circuit of claim 19, wherein the delay cell includes an inverter string.

21. A circuit configured for providing hot-carrier effect protection, the circuit comprising:
a conductive pad at which a signal of a first voltage level or a reference level is received during a receiving mode and from which a signal of a second voltage level or the reference voltage level is transmitted;
a first transistor including a first terminal and a second terminal;
a second transistor including a third terminal coupled to the first terminal and a fourth terminal coupled to the conductive pad; and
a first control circuit configured for maintaining a voltage across the first terminal and the second terminal of the first transistor at a level below approximately the first voltage level minus the second voltage level during a first transition from the receiving mode when receiving a signal of the first voltage level to the transmitting mode when transmitting a signal of the second voltage level.

22. The circuit of claim 21 further comprising:
a third transistor including a fifth terminal coupled to the third terminal and a sixth terminal coupled to the fourth terminal.

23. The device of claim 22, wherein the first control circuit is configured for maintaining a voltage across the fifth terminal and the sixth terminal of the third transistor at a level below approximately the first voltage level minus the second voltage level during the first transition.

24. The circuit of claim 21 further comprising:
a fourth transistor including a pair of terminals, one of the pair of terminals being coupled to the conductive pad; and
a second control circuit configured for maintaining a voltage across the pair of terminals of the fourth transistor at a level below approximately the first voltage level minus the second voltage level during a second transition from the receiving mode when receiving a signal of the first voltage level to the transmitting mode when transmitting a signal of the reference level.

25. The device of claim 24 further comprising a fifth transistor, wherein the fifth transistor includes a pair of terminals, one of the pair of terminals being coupled to the conductive pad.

26. The circuit of claim 25 further comprising:
a sixth transistor including a pair of terminals, one of the pair of terminals being coupled to the other terminal of the fifth transistor; and
a third control circuit configured for maintaining a voltage across the pair of terminals of the sixth transistor at a level below approximately the first voltage level minus the second voltage level during the second transition.

27. The circuit of claim 26 further comprising a level shifter configured for providing the first voltage level during the transmitting mode, and providing the second voltage level during the receiving mode.

28. The device of claim 27, wherein at least one of the first, second or third control circuit includes a seventh transistor further including a gate coupled to an output of the level shifter.

29. The circuit of claim 21 further comprising a delay cell coupled to a pre-driver.

30. The circuit of claim 29, wherein the delay cell includes an inverter string.

31. A method of protecting a circuit from hot-carrier effect protection, the method comprising:
providing a first transistor including a first terminal and a second terminal;
coupling the first terminal of the first transistor to a conductive pad;
providing a switch device including a terminal;
coupling the terminal of the switch device to the conductive pad;
keeping the switch at an off state during a receiving mode at which a signal of a first voltage level or a reference level is received at the conductive pad;
keeping the switch at the off state during a transmitting mode from which a signal of a second voltage level or the reference level is transmitted at the conductive pad;
keeping the switch at an on state during a transition from the receiving mode when receiving a signal of the first voltage level to the transmitting mode when transmitting a signal having the reference voltage level; and
maintaining a voltage across the first terminal and the second terminal of the first transistor at a level below approximately the first voltage level minus the second voltage level during the transition.

32. The method of claim 31, wherein the switch device includes a second transistor, further comprising coupling a gate of the second transistor to the control circuit.

33. The method of claim 32 further comprising providing a level shifter, wherein the level shifter is configured for providing the first voltage level during the transmitting mode, and providing the second voltage level during the receiving mode.

34. The circuit of claim 33 further comprising providing a third transistor, wherein the third transistor includes a gate coupled to an output of the level shifter and a terminal coupled to the gate of the second transistor.

35. The circuit of claim 33 further comprising providing a fourth transistor, wherein the fourth transistor includes a gate coupled to the conductive pad and a terminal coupled to the gate of the second transistor.
